(19) United States
(12) Patent Application Publication
(10) Pub. No.: US 2015/0325303 A1
(43) Pub. Date: Nov. 12, 2015

(54) SEMICONDUCTOR MEMORY DEVICE

(71) Applicant: KABUSHIKI KAISHA TOSHIBA, Tokyo (JP)

(72) Inventors: Toshifumi HASHIMOTO, Fujisawa Kanagawa (JP); Noboru SHIBATA, Kawasaki Kanagawa (JP)

(21) Appl. No.: 14/630,511

(22) Filed: Feb. 24, 2015

(30) Foreign Application Priority Data
May 8, 2014 (JP) 2014-097189

(51) Int. Cl. G11C 16/16; G11C 16/08

(52) U.S. Cl. CPC G11C 16/16; G11C 16/08

(57) ABSTRACT

A semiconductor memory device includes adjacent first and second blocks of memory cells, wherein all the memory cells in each block are erased collectively and each of the blocks includes a plurality of stacks of memory cells above a semiconductor substrate, a dummy cell region including a plurality of stacks of dummy cells above the semiconductor substrate, a source line contact electrically connected to an upper wiring layer and through which a voltage is applied to a source line of the memory cells, and a substrate contact electrically connected to the upper wiring layer and through which a voltage is applied to the semiconductor substrate. The source line contact is disposed between the first and second blocks, and the substrate contact is separated from any of the stacks of memory cells by at least one stack of dummy cells.

### CROSS-REFERENCE TO RELATED APPLICATION

This application is based upon and claims the benefit of priority from Japanese Patent Application No. 2014-097189, filed May 8, 2014, the entire contents of which are incorporated herein by reference.

### FIELD

Embodiments described herein relate generally to a semiconductor memory device.

### BACKGROUND

A NAND type flash memory in which memory cells are three-dimensionally arranged, is known as a semiconductor memory device.

### DESCRIPTION OF THE DRAWINGS

FIG. 1 is a block diagram of a semiconductor memory device according to a first embodiment.

FIG. 2A and FIG. 2B are circuit diagrams illustrating a portion of a memory cell array according to the first embodiment.

FIG. 3 is a circuit diagram illustrating a portion of a row decoder according to the first embodiment.

FIG. 4 is a layout diagram illustrating a portion of the memory cell array according to the first embodiment.

FIG. 5A and FIG. 5B are cross-sectional views taken along line A-A of FIG. 4.

FIG. 6 is a layout diagram illustrating a portion of a memory cell array according to a comparative example.

FIG. 7A and FIG. 7B are cross-sectional views taken along line A-A of FIG. 6.

FIG. 8 is a layout example of the memory cell array according to the first embodiment.

FIG. 9 is a layout example of the memory cell array according to the first embodiment.

FIG. 10 is a layout example of the memory cell array according to the first embodiment.

FIG. 11 is a layout example of the memory cell array according to the first embodiment.

FIG. 12 is a layout example of the memory cell array according to the first embodiment.

FIG. 13 is a block diagram of a memory cell array and a row decoder according to a second embodiment.

FIG. 14 is a layout example of a memory cell array according to a modification example of the second embodiment.

FIG. 15 is a block diagram of a memory cell array and a row decoder according to a modification example of the second embodiment.

FIG. 16 is a layout example of a memory cell array according to a modification example of the second embodiment.

FIG. 17 is a block diagram of a memory cell array and a row decoder according to a modification example of the second embodiment.

### DETAILED DESCRIPTION

The present embodiment now will be described more fully hereinafter with reference to the accompanying drawings, in which various embodiments are shown. In the drawings, the thickness of layers and regions may be exaggerated for clarity. Like numbers refer to like elements throughout. As used herein the term “and/or” includes any and all combinations of one or more of the associated listed items and may be abbreviated as “/”.

The terminology used herein is for the purpose of describing particular embodiments only and is not intended to be limiting of the invention. As used herein, the singular forms “a, ” “an” and “the” are intended to include the plurality of forms as well, unless the context clearly indicates otherwise. It will be further understood that the terms “comprises,” “comprising,” “having,” “includes,” “including” and/or variations thereof, when used in this specification, specify the presence of stated features, regions, steps, operations, elements, and/or components, but do not preclude the presence or addition of one or more other features, regions, steps, operations, elements, components, and/or groups thereof.

It will be understood that when an element such as a layer or region is referred to as being “on” or extending “onto” another element (and/or variations thereof), it may be directly on or extend directly onto the other element or intervening elements may also be present. In contrast, when an element is referred to as being “directly on” or extending “directly onto” another element (and/or variations thereof), there are no intervening elements present. It will also be understood that when an element is referred to as being “connected” or “coupled” to another element (and/or variations thereof), it may be directly connected or coupled to the other element or intervening elements may be present. In contrast, when an element is referred to as being “directly connected” or “directly coupled” to another element (and/or variations thereof), there are no intervening elements present.

It will be understood that, although the terms first, second, etc. may be used herein to describe various elements, components, regions, layers and/or sections, these elements, materials, regions, layers and/or sections should not be limited by these terms. These terms are only used to distinguish one element, material, region, layer or section from another element, material, region, layer or section. Thus, a first element, material, region, layer or section discussed below could be termed a second element, material, region, layer or section without departing from the teachings of the present invention.

Relative terms, such as “lower”, “back”, and “upper” may be used herein to describe one element's relationship to another element as illustrated in the Figures. It will be understood that relative terms are intended to encompass different orientations of the device in addition to the orientation depicted in the Figures. For example, if the structure in the Figure is turned over, elements described as being on the “backside” of substrate would then be oriented on “upper” surface of the substrate. The exemplary term “upper”, may therefore, encompasses both an orientation of “lower” and “upper,” depending on the particular orientation of the figure. Similarly, if the structure in one of the figures is turned over, elements described as “below” or “beneath” other elements would then be oriented “above” the other elements. The exemplary terms “below” or “beneath” can, therefore, encompass both an orientation of above and below.

Embodiments are described herein with reference to cross section and perspective illustrations that are schematic illustrations of idealized embodiments. As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing. For example, a region illustrated as flat may, typically, have rough and/or nonlinear features. Moreover, sharp angles that are illustrated, typically, may be rounded. Thus, the regions illustrated in the figures are schematic in nature and their shapes are not intended to illustrate the precise shape of a region and are not intended to limit the scope of the present invention.

The embodiments provide a semiconductor memory device that improves reliability of data reading.

In general, according to one embodiment, a semiconductor memory device includes a memory cell region including adjacent first and second blocks of memory cells, wherein all the memory cells in each block are erased collectively and each of the blocks includes a plurality of stacks of memory cells above a semiconductor substrate, a dummy cell region including a plurality of stacks of dummy cells above the semiconductor substrate, a source line contact electrically connected to an upper wiring layer and through which a voltage is applied to a source line of the memory cells, wherein the source line contact is in contact with the semiconductor substrate and disposed between the first and second blocks, and a substrate contact electrically connected to the upper wiring layer and through which a voltage is applied to the semiconductor substrate, wherein the substrate contact is in contact with the semiconductor substrate and is separated from any one of the stacks of memory cells by at least one stack of dummy cells.

As a NAND type flash memory, a bit cost scalable (BiCS) memory in which a plurality of memory cells are stacked in a vertical direction within a memory cell array, may be used. In the NAND type flash memory, contacts which are connected to a lower layer structure and an upper layer structure of the memory cell array, are provided. The contacts includes a source line contact, and a substrate contact.

However, in the memory cell which is adjacent to the substrate contact, a current path is not formed on the substrate contact side, and a cell current flowing in the memory cell maybe disturbed. Accordingly, resistance of the source line which is connected to such memory cell, may increase more than the resistance of the source line that is connected to another memory cell which is not adjacent to the substrate contact. Hence, cell properties may be changed in comparison with another memory cell.

According to the embodiments described below, it is possible to suppress the change of the cell properties described above. That is, a semiconductor memory device of the embodiment includes a memory cell region including a memory cell, and a dummy cell region including a dummy cell. The memory cell region and the dummy cell region are disposed above a semiconductor substrate. Moreover, the semiconductor memory device of the embodiment includes a source line contact through which a current flows to the memory cell, and a substrate contact that applies a voltage to the semiconductor substrate. The source line contact and the substrate contact are electrically connected to an upper wiring layer and the memory cell. According to embodiments, the substrate contact is provided only within the dummy cell region.

The semiconductor memory device according to the embodiments, will be described with reference to the drawings. In the drawings, the same reference signs are attached to the same portions. Moreover, the overlapping description will be performed as necessary.

### FIRST EMBODIMENT

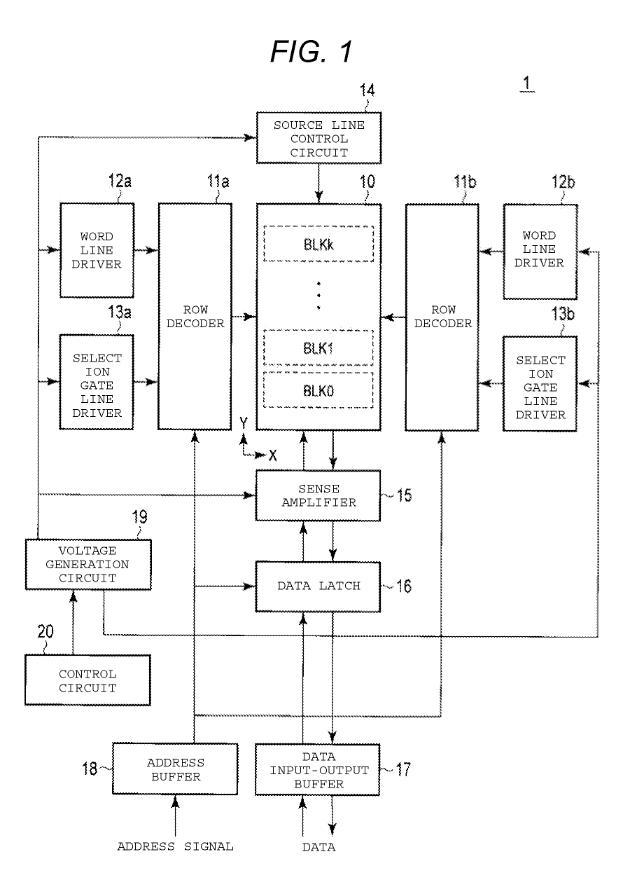

Hereinafter, a semiconductor memory device according to a first embodiment, will be described using FIG. 1 to FIG. 5B.

### (1) Configuration of Semiconductor Memory Device

A configuration example of the semiconductor memory device according to the first embodiment, will be described. In the following description, a case of being simply referred to as being “connected”, means being physically connected, and also includes being directly connected, or being indirectly connected through another element. A case of being referred to as being “electrically connected”, means an electrically conducting state, and also includes being directly connected, or being indirectly connected through another element.

### Summary Configuration Example of Semiconductor Memory Device

FIG. 1 illustrates a NAND type flash memory 1 as a semiconductor memory device according to the first embodiment, which has, for example, a structure in which the memory cells are three-dimensionally above the semiconductor substrate.

The NAND type flash memory 1 includes a memory cell array 10, a row decoder 11 (11a, 11b), a word line driver 12 (12a, 12b), a selection gate line driver 13 (13a, 13b), a source line control circuit 14, a sense amplifier 15, a data latch 16, a data input-output buffer 17, an address buffer 18, a voltage generation circuit 19, and a control circuit 20.

The memory cell array 10 includes a plurality of memory blocks BLK (BLK0 to BLKk). The individual memory blocks BLK each include a group of nonvolatile memory cells. As described later, the number of the memory blocks, and the layout thereof are arbitrary within the memory cell array 10.

A NAND string includes a plurality of memory cells. Each of the memory cells within the NAND string, are connected to each other in series in a vertical direction. A word line is connected to a gate of each memory cell. A bit line is connected to a drain of the memory cell of one end side of the NAND string, and a source line is connected to a source of the memory cell of the other end side. Such configuration of the NAND string will be described later.

The row decoder 11 selects an X direction (row direction) of the memory cell array 10. Specifically, the row decoder 11 selects one of the blocks, based on an address signal, at the time of writing the data, and at the time of reading the data.

The word line driver 12 applies the needed voltage to the selected word line and the non-selected word line, through the row decoder 11. The selection gate line driver 13 applies the needed voltage to the selected selection gate line and the non-selected selection gate line, through the row decoder 11. The source line control circuit 14 controls the voltage of each source line based on the address signal and the data.

The sense amplifier 15 is electrically connected to the memory cell which is connected to the selected word line, through the bit line. The sense amplifier 15 performs the sense and the amplification of the read data in the bit line, at the time of reading the data. The sense amplifier 15 performs the transfer of the write data to the bit line, at the time of writing the data.

The data latch 16 retains the read data which is sensed and amplified by the sense amplifier 15. The data latch 16 includes, for example, a flip flop circuit. The data input-output buffer 17 receives the data from the outside, and supplies the data to the data latch 16. Moreover, the data input-output buffer 17 outputs the data to the outside from the data latch 16.

The address buffer 18 receives the address signal from the outside, and supplies the address signal to the row decoder 11 and the data latch 16.

The voltage generation circuit 19 generates the needed voltage for the writing, the reading, and the erasing of the data, for example, in response to command from the control circuit 20. The voltage generation circuit 19 supplies the generated voltage to the word line driver 12, the selection gate line driver 13, the source line control circuit 14, and the sense amplifier 15.

The control circuit 20 controls the entire operations of the NAND type flash memory 1, according to a command which is received from the outside. For example, various control signals in the following description, are generated by the control circuit 20.

### Memory Cell Array

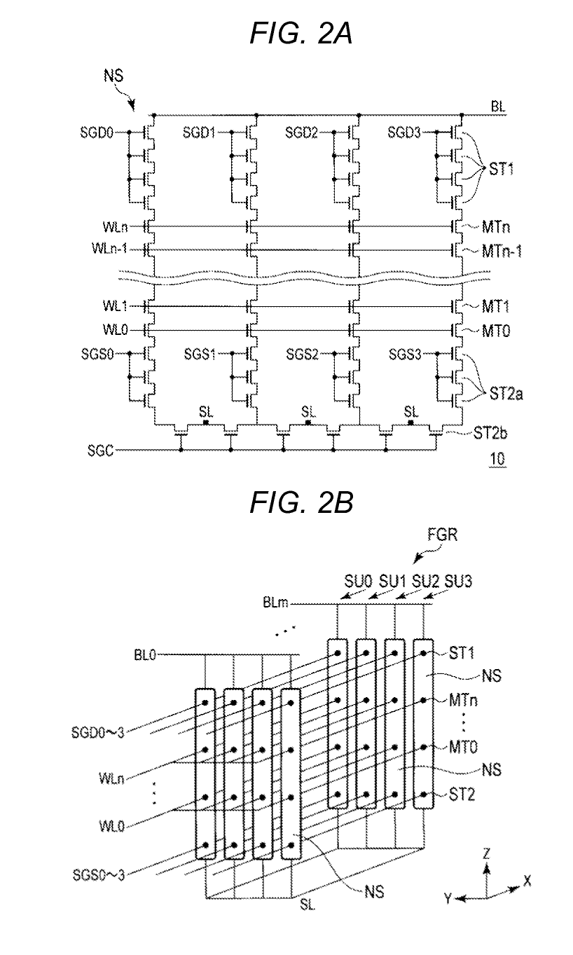

Using circuit diagrams of FIG. 2A and FIG. 2B, a memory cell array according to the first embodiment will be described.

The memory blocks BLK of FIG. 1 include a plurality of fingers FGR. The individual fingers FGR include a plurality of string units SU. For example, the individual string units SU include one column of the array of NAND strings NS which are lined up in the X direction (row direction). FIG. 2B indicates one finger FGR among the plurality of fingers FGR. FIG. 2A indicates the NAND strings NS which are connected to the same bit line BL described later in common within one finger FGR. The number of the arrays of the string units SU within the fingers FGR, and the number of the fingers FGR within the memory blocks BLK are arbitrary. In FIG. 2A and FIG. 2B, an example in which one finger FGR includes four string units SU, is indicated.

As illustrated in FIG. 2A and FIG. 2B, the NAND strings NS are provided in a matrix shape within the memory cell array 10. Each of the NAND strings NS includes a plurality of memory cell transistors MT (MT0 to MTn), and selection gate transistors ST1 and ST2 (ST2a, ST2b). The selection gate transistors ST1 and ST2 include a plurality (separately four in FIG. 2A and FIG. 2B) of transistors, respectively.

The memory cell transistor MT (referred to as the memory cell) includes a stacked gate including a control gate and an electric charge accumulating film. The memory cell transistor MT is a memory element which may retain data in a nonvolatile manner. The memory cell transistor MT is connected so that the current path thereof is in series, between the selection gate transistors ST1 and ST2. The memory cell transistor MTn is disposed on one end side of the series connection, and the memory cell transistor MT0 is disposed on the other end side. One end of the current path of the memory cell transistor MTn is connected to one end of the current path of the selection gate transistor ST1. The other end of the current path of the memory cell transistor MT0 is connected to one end of the current path of the selection gate transistor ST2.

In the plurality of NAND strings NS which are included in the same string unit SU, each gate of the selection gate transistor ST1 is connected to a selection gate line SGD in common. For example, in a string unit SU0, the gate of the selection gate transistor ST1 of each of the NAND strings NS which are lined up in 0-th column, is connected to a selection gate line SGD0 in common.

In the same manner, in the plurality of NAND strings NS which are included in the same string unit SU, each gate of the selection gate transistor ST2a is connected to a selection gate line SGS in common. For example, in the string unit SU0, the gate of the selection gate transistor ST2a of each of the NAND strings NS which are lined up in 0-th column, is connected to a selection gate line SGS0 in common.

The gates of all selection gate transistors ST2b which are included in the same finger FGR, are connected to a selection gate line SGC in common.

Within the same finger FGR, the gates of the memory cell transistors MT0 of all NAND strings NS, are connected to a word line WL0 in common. Similarly, in the same finger FGR, the gates of the memory cell transistors MTi (1≦i≦n) of all NAND strings NS, are connected to a word line WLi in common.

The NAND string NS which is disposed in the Y direction (column direction), is connected to the same bit line BL. The bit line BL is connected to the plurality of NAND strings NS which are lined up in the Y direction in common, among the plurality of memory blocks BLK.

One end of the current path of the selection gate transistor ST1 is connected to the bit line BL (BL0 to BLm). The NAND string NS within the same finger FGR, is connected to the same source line SL.

The data of the memory cell transistors MT which are disposed within the same block BLK, is collectively erased. The writing and the reading of the data are collectively performed per memory cell transistor, with respect to the plurality of memory cell transistors MT which are connected to any one word line WL in common in any one string unit SU among one finger FGR. The unit at this time, becomes “page”.

Furthermore, the data may be erased per finger FGR unit within the block BLK, or the plurality of string units SU only may be erased.

For example, two values of “1” and “0” are present in the data which is retained by the memory cell transistor MT (memory cell). At the time of the writing, the reading, and the erasing of the data, the needed voltage is applied to the bit line BL, the source line SL, the selection gate lines SGD, SGS and SGC, and the word line WL. Hereby, during writing the data, the electrical charge is appropriately retained in the memory cell, and a threshold voltage of the memory cell is changed. During reading the data, the cell current flows to the memory cell by the current path leading to the source line SL from the bit line BL. At this time, the memory cell becomes in an ON state or an OFF state, and thereby, the data which is retained in the memory cell, is identified. At the time of erasing the data, the voltage is applied to a p-type well of the semiconductor substrate. As a result, the retained electrical charge of the memory cell is pulled out to the p-type well, and the data is erased from the memory cell.

### Row Decoder

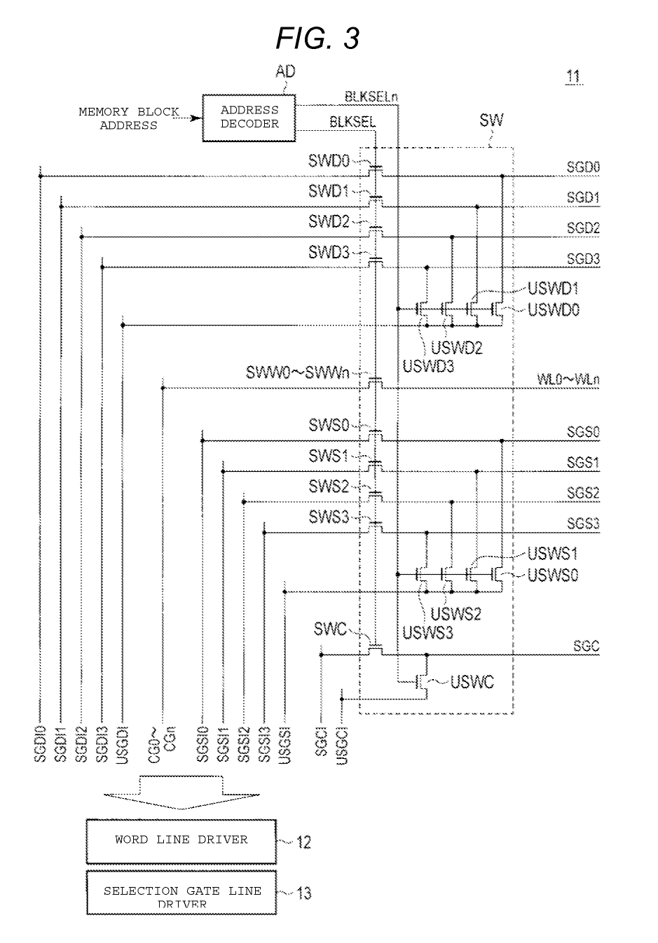

As illustrated in FIG. 3, the row decoder 11 includes an address decoder AD, and a transfer switch group SW per memory block BLK.

The transfer switch group SW includes switches SWD, SWS and SWC, switches USWD, USWS and USWC, and a word line switch SWW. The selection gate lines SGD, SGS and SGC, and the word line WL are connected to the selection gate line driver 13, and the word line driver 12 illustrated in FIG. 1, through the transfer switch group SW.

The selection gate line SGD0 is connected to one end of a switch SWD0. The other end of the switch SWD0 is connected to a wiring SGDI0. Another selection gate line SGDj (1≦j≦3) is connected to one end of a switch SWDj. The other end of the switch SWDj is connected to a wiring SGDIj.

The selection gate line SGD0 is connected to a switch USWD0, and a selection gate line SGD1 is connected to a switch USWD1, and a selection gate line SGD2 is connected to a switch USWD2, and a selection gate line SGD3 is connected to a switch USWD3. The switches USWD0 to USWD3 are connected to a wiring USGDI. To the wiring SGDI and the wiring USGDI, various voltages are supplied from the selection gate line driver 13. Various voltages are transferred to the selection gate line SGD.

The selection gate line SGS0 is connected to one end of a switch SWS0. The other end of the switch SWS0 is connected to a wiring SGSI0. Another selection gate line SGSj (1≦j≦3) is connected to one end of a switch SWSj. The other end of the switch SWSj is connected to a wiring SGSIj.

The selection gate line SGS0 is connected to a switch USWS0, and a selection gate line SGS1 is connected to a switch USWS1, and a selection gate line SGS2 is connected to a switch USWS2, and a selection gate line SGS3 is connected to a switch USWS3. The switches USWS0 to USWS3 are connected to a wiring USGSI. To the wiring SGSI and the wiring USGSI, various voltages are supplied from the selection gate line driver 13. Various voltages are transferred to the selection gate line SGS.

The selection gate line SGC is connected to the switch SWC. The switch SWC is connected to a wiring SGCI. The selection gate line SGC is connected to the switch USWC. The switch UWSC is connected to a wiring USGCI. To the wiring SGCI and the wiring USGCI, various voltages are supplied from the selection gate line driver 13. Various voltages are transferred to the selection gate line SGC.

The word line WL (WL0 to WLn) is connected to the word line switch SWW (SWW0 to SWWn). The word line switch SWW is connected to a wiring CG (CG0 to CGn). To the wiring CG, various voltages are supplied from the word line driver 12. Various voltages are transferred to the word line WL.

Based on a memory block address signal which is received from the address buffer 18, the address decoder AD selects or does not select the memory block BLK which is assigned thereto. That is, the address decoder AD of the selected memory block BLK, outputs a signal BLKSEL. Hereby, the switches SWD, SWS and SWC, and the word line switch SWW are turned on. The switches USWD, USWS and USWC are turned off. Consequently, the row decoder 11 transfers various voltages to the selection gate lines SGD and SGS, and the word line WL. The address decoder AD of the non-selected memory block BLK, outputs a signal BLKSELn. Hereby, the switches USWD, USWS and USWC are turned on. The row decoder 11 turns off the switches SWD, SWS and SWC, and the word line switch SWW.

The selection gate line driver 13 controls the selection or the non-selection of the NAND string NS. That is, the selection gate line driver 13 sets the voltage that is transferred from the wiring SGDI and the wiring SGSI which are assigned to the selected string unit SU, to a voltage for the selection. Moreover, the selection gate line driver 13 sets the voltage that is transferred from the wiring SGDI and the wiring SGSI which are assigned to the non-selected string unit SU, to a voltage for the non-selection. Additionally, the word line driver 12 performs the selection of the word line WL. That is, the word line driver 12 sets the voltage which is transferred from the wiring CG, to a suitable voltage.

### Source Line Contact and Substrate Contact

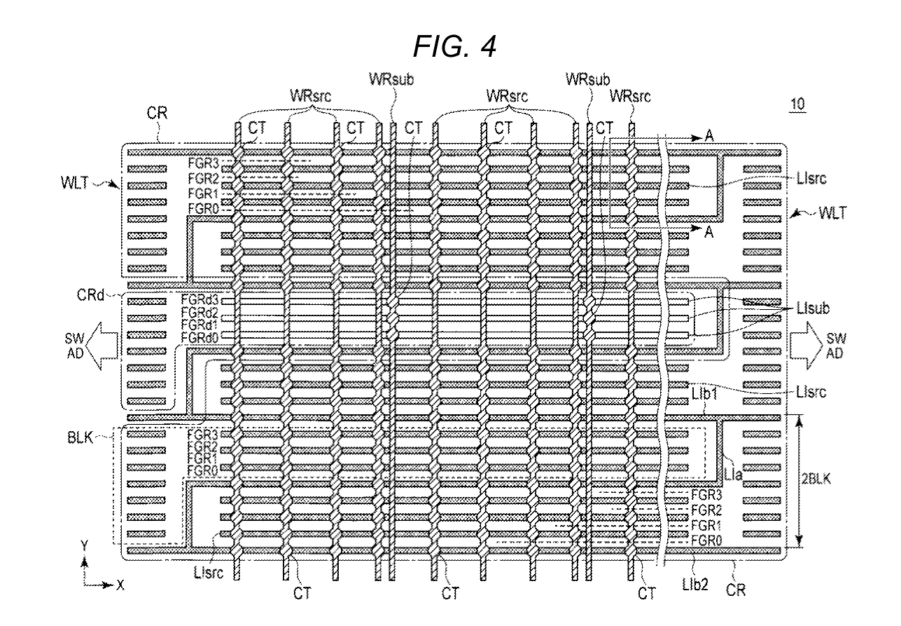

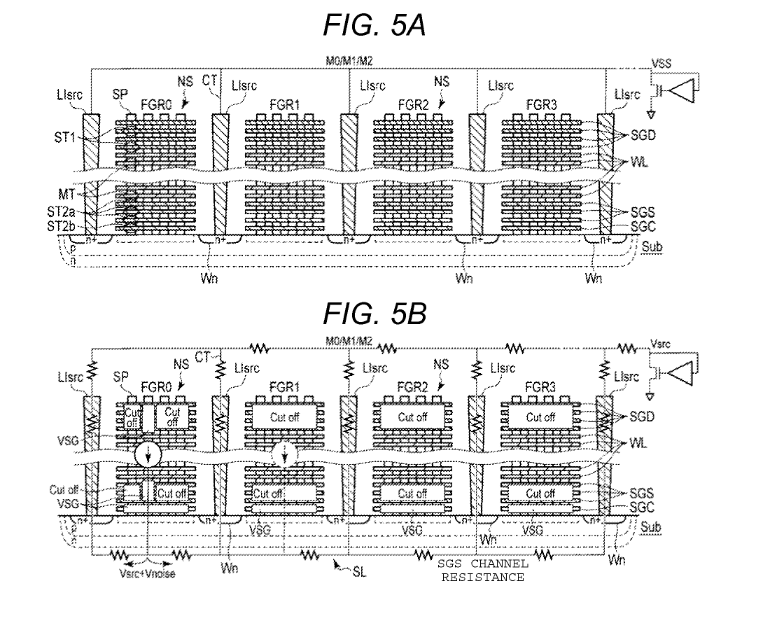

A source line contact LIsrc and a substrate contact LIsub which are included in the NAND type flash memory 1 according to the first embodiment, will be described using FIG. 4, FIG. 5A and FIG. 5B.

As illustrated in FIG. 4, FIG. 5A and FIG. 5B, the memory cell array 10 includes a plurality of plate-shaped contacts LI. The plate-shaped contact LI is connected to a semiconductor substrate Sub, and a wiring layer WR which is provided above the memory cell array 10. The wiring layer WR includes two types of wiring layers WRsrc and WRsub. For convenience of the description, among the plate-shaped contacts LI, a contact which is connected to the semiconductor substrate Sub and the wiring layer WRsrc, is referred to as a source line contact LIsrc, and a contact which is connected to the semiconductor substrate Sub and the wiring layer WRsub, is referred to as a substrate contact LIsub.

The memory cell array 10 includes a memory cell region CR, and a dummy cell region CRd. The source line contact LIsrc is disposed in the memory cell region CR, and the substrate contact LIsub is disposed in the dummy cell region CRd. In other words, at least within the memory cell array 10, the substrate contact LIsub is provided only within the dummy cell region CRd. However, the source line contact LIsrc may be disposed in the dummy cell region CRd. Moreover, the substrate contact LIsub may be provided in a region other than the memory cell array, for example, an outer peripheral portion.

Within the memory cell region CR, between each of the source line contacts LIsrc, the fingers FGR (FGR0 to FGR3) are disposed, for example, one by one. Within the dummy cell region CRd, between each of the substrate contacts LIsub, dummy fingers FGRd (FGRd0 to FGRd3) are disposed, for example, one by one.

Alternatively, any one of the substrate contacts LIsub which are disposed within the dummy cell region CRd, may be the source line contact LIsrc. For example, the center sheet among three sheets of the plate-shaped contacts LI within the dummy cell region CRd illustrated in FIG. 4, may be the source line contact LIsrc.

One memory block BLK within the memory cell region CR, includes the plurality (four in FIG. 4, FIG. 5A and FIG. 5B) of fingers FGR. In the example of FIG. 4, among the memory cell array 10, two blocks BLK which are adjacent to each other in the Y direction, form one set. Such one set includes the memory block BLK where a word line terrace WLT is disposed on a positive side of the X direction, and the memory block BLK where the word line terrace WLT is disposed on a negative side of the X direction. That is, the word line terraces WLT are configured so that the word lines WL of each of the memory blocks BLK are pulled out to the sides which are different from each other in the memory cell array 10. On the border between two memory blocks BLK which are adjacent to each other, for example, a plate-shaped contact LIa is disposed. On the border between the memory blocks BLK of one set, and the memory blocks BLK of one set which are adjacent thereto, a plate-shaped contact LIb is disposed.

One end of the plate-shaped contact LIa having a crank shape, is connected to a plate-shaped contact LIb1. The other end of the plate-shaped contact LIa having the crank shape, is connected to a plate-shaped contact LIb2. The plate-shaped contacts LIa and LIb which are disposed on the border of the memory blocks BLK, may be considered as a portion of any one of the memory blocks BLK which are adjacent to each other. In the example of FIG. 4, the plate-shaped contacts LIa and LIb of the border of the memory blocks BLK, are configured as a source line contact LIsrc, as can be seen from FIG. 5A and FIG. 5B.

The word line terraces WLT are provided on both sides in the X direction of the region where the plate-shaped contact LI, the finger FGR, and the dummy finger FGRd are provided. Further outside of the word line terrace WLT, the row decoder 11 including the address decoder AD and the transfer switch group SW, is provided. The word line terrace WLT is equivalent to a pullout portion of the word line WL. In the word line terrace WLT, each word line WL is connected to the wiring layer (not illustrated) which is provided above the memory cell array 10. Each word line WL is connected to the word line switch SWW within the row decoder 11.

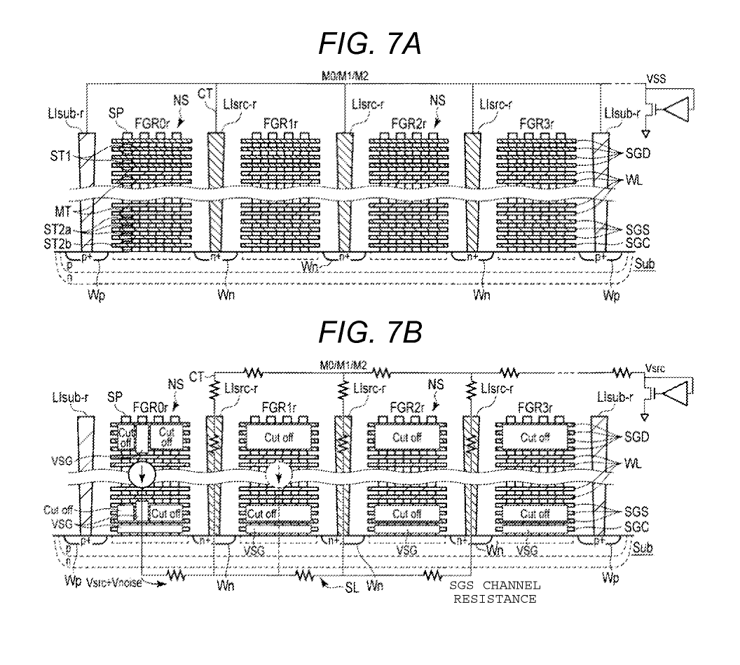

As described above, each of the plate-shaped contacts LI are connected to a lower layer structure (semiconductor substrate Sub) and an upper layer structure (wiring layer WR) of the memory cell array 10. More specifically, as illustrated in FIG. 5A and FIG. 5B, the plate-shaped contact LI is connected to the wiring layer WR of the upper layer, and is a pillar-shaped contact CT that is provided on a diffusion layer W which is provided within the well of the semiconductor substrate Sub. The diffusion layer W includes an n-type diffusion layer Wn, and a p-type diffusion layer Wp (see FIG. 7A and FIG. 7B). An n-type well is provided in the semiconductor substrate Sub, and the p-type well is provided in the n-type well. The diffusion layers Wn and Wp are provided in the p-type well, respectively. The wiring layer WR includes a plurality of metal wiring layers where an M0 layer, an M1 layer, an M2 layer and the like are provided. The wiring layers WRsrc and WRsub are disposed in, for example, the M1 layer. The wiring layer WRsrc forms a portion of the source line SL, and the wiring layer WRsub applies a voltage to the semiconductor substrate Sub. The wiring layer WRsrc includes a main wiring layer, and a shunt wiring layer as subsidiary wiring of the main wiring layer. The source line SL includes a channel which is formed in the vicinity of surface layers of the wiring layer WRsrc, the source line contact LIsrc, and the semiconductor substrate Sub, as a current path. The source line contact LIsrc is arranged on the n-type diffusion layer Wn, and is connected to the wiring layer WRsrc. The substrate contact LIsub is provided on the p-type diffusion layer Wp, and is connected to the wiring layer WRsub.

As described above, the NAND string NS which is included in each finger FGR, includes the memory cell transistor MT, and the selection gate transistors ST1 and ST2. Within the memory cell array 10, a silicon pillar SP is provided in the vertical direction. Each of the transistors MT, ST1 and ST2 are connected to each other in series in the vertical direction, with the silicon pillar SP disposed as a central axis. That is, each of the transistors MT, ST1 and ST2 are disposed in the region including the silicon pillar SP, the word line WL which is provided in multiple layers, and the selection gate lines SGD, SGS and SGC.

The dummy finger FGRd which is provided within the dummy cell region CRd, includes the plurality of arrays in the X direction (row direction) of the dummy cells which are three-dimensionally disposed. The dummy cell may be configured in the same manner as the memory cell. The dummy finger FGRd may include the NAND string including the dummy cells. More specifically, such NAND string may include the memory cell transistor, and two types of the selection gate transistors. The dummy finger FGRd may include the string unit that includes the array in the X direction (row direction) of the NAND strings.

### (2) Operations of Semiconductor Memory Device

Next, an example in which the data is read from the finger FGR0 within the arbitrary memory block BLK, will be described mainly using FIG. 5B. Specifically, in FIG. 5B, an example in which the data is read from the second string unit SU from the left within the finger FGR0, will be described. The operations of the NAND type flash memory 1 described below, are performed by the control circuit 20 of FIG. 1 which receives an instruction from the outside.

In the following description, the NAND string NS of a reading target is referred to as a selected NAND string NS, and the NAND string NS other than the selected NAND string NS, is referred to as a non-selected NAND string NS. The finger FGR and the memory block BLK which include the selected NAND string NS, are referred to as a selected finger FGR and a selected memory block BLK, respectively. The finger FGR and the memory block BLK which do not include the selected NAND string NS, are referred to as a non-selected finger FGR and a non-selected memory block BLK, respectively.

As illustrated in FIG. 5A, a voltage Vss (ground voltage, for example, 0 V) is given to the source line contact LIsrc before a reading operation. As illustrated in FIG. 5B, at the time of the reading operation, in the selected memory block BLK, a source line voltage Vsrc is applied to all source line contacts LIsrc, through the wiring layer WRsrc. Moreover, the needed voltage (for example, precharge voltage) for the reading is applied to the bit line BL. The reading voltage is applied to the selected word line WL (not illustrated in FIG. 5A and FIG. 5B).

Additionally, in the selected NAND string NS which is disposed within the finger FGR0, a voltage VSG from the selection gate line driver 13, is transferred to the selection gate transistors ST1 and ST2 from the wiring SGDI, the wiring SGSI and the wiring SGCI. Hereby, the voltage VSG is applied to the selection gate transistors ST1 and ST2 of the selected NAND string NS, and the selection gate transistors ST1 and ST2 are entirely turned on. Moreover, in the non-selected NAND string NS within the selected memory block BLK, the voltage for the non-selection from the selection gate line driver 13, is transferred to the selection gate transistors ST1 and ST2a from the wiring USGDI and the wiring USGSI. Hereby, the selection gate transistors ST1 and ST2a of the non-selected NAND string NS, are maintained in the OFF state. Among the plurality of transistors which are included in the selection gate transistor ST2, the voltage VSG is transferred to the selection gate transistor ST2b of the lowest layer from the wiring SGCI, through the selection gate line SGC. Hereby, the voltage VSG is applied to the selection gate transistor ST2b, and the selection gate transistor ST2b only is turned on.

In this manner, the selection gate transistor ST2b of the lowest layer is turned on, and thereby, the channel is formed between each of the n-type diffusion layers Wn which are provided below the source line contact LIsrc. Moreover, the selection gate transistor ST2b of the lowest layer is turned on, and thereby, it is possible to reduce the resistance (SGS channel resistance) of the channel between the n-type diffusion layers Wn. Accordingly, it is possible to lower the resistance of the source line SL.

The source line voltage Vsrc which is applied to the selected NAND string NS within the finger FGR0, is changed by various resistances. For example, various resistances include the resistance of various wiring layers WR and various contacts CT and LIsrc of the M0 layer, the M1 layer, and the M2 layer. Moreover, a leakage current flowing into the non-selected NAND string NS, may be generated. The resistances and the leakage current increase the source line voltage Vsrc which becomes a noise voltage Vnoise.

However, in the configuration according to the first embodiment, as described later, the reduction and the unevenness of the source line voltage Vsrc within the selected memory block BLK, are very slight.

From the above, in the selected NAND string NS within the finger FGR0, the cell current flows into the memory cell, and the data is read from the memory cell.

Furthermore, the reading operation as an example is described, but a writing operation, and an erasing operation are similar thereto. During writing the data, and at the time of erasing the data, the needed source line voltage is appropriately applied to the source line contact LIsrc within the selection memory block BLK. Hereby, a desired operation is performed.

### (3) Effects according to First Embodiment

In the first embodiment, one or a plurality of effects will be achieved.

(A) According to the first embodiment, the memory cell array 10 includes the memory cell region CR, and the dummy cell region CRd. Within the memory cell array 10, the substrate contact LIsub is provided only within the dummy cell region CRd.

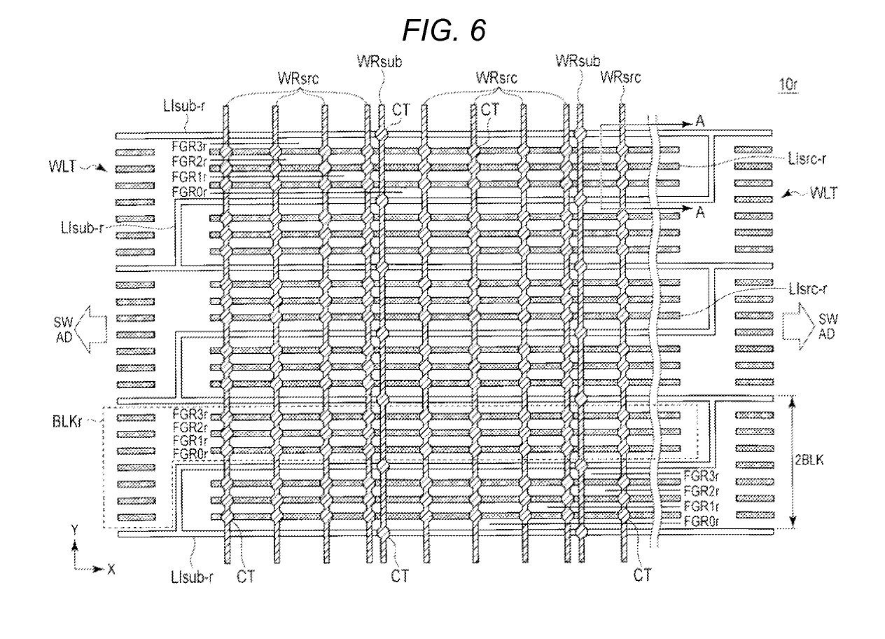

Comparative examples illustrated in FIG. 6, FIG. 7A and FIG. 7B, are examples in which the dummy cell region CRd is not provided, and a substrate contact LIsub_r is appropriately disposed within a memory cell array 10r. Using such comparative examples, the effects of the first embodiment will be described. In the examples of FIG. 6, FIG. 7A and FIG. 7B, the substrate contact LIsub_r is provided on the border of each memory block BLKr. That is, the plate-shaped contact which is disposed on the border of each memory block BLKr, is configured as a substrate contact LIsub_r. In this manner, the substrate contacts LIsub_r are provided on one side of a finger FGR0r and one side of a finger FGR3r, respectively.

FIG. 7B indicates an example in which the data is read from the finger FGR0r within the arbitrary memory block BLKr (specifically, the second string unit SU from the left within the finger FGR0r). In this case, in the selection memory block BLKr, the source line voltage Vsrc is applied to all source line contacts LIsrc_r, through the wiring layer WR.

However, in the finger FGR0r, one side thereof is adjacent to the substrate contact LIsub_r. Hence, the source line voltage Vsrc is not applied only from the source line contact LIsub_r of the other side. Therefore, the current path is not formed on the substrate contact LIsub_r side of the finger FGR0r. As a result, in comparison with the fingers FGR1r and FGR2r to which the source line voltage Vsrc is applied from both sides, the potential of the source line voltage Vsrc in the vicinity of the finger FGR0r, may locally rise. That is, by a position of the selected finger FGRr, the value of the source line voltage Vsrc is changed, and the cell properties may be changed.

In the first embodiment, at least within the memory cell array, the substrate contact LIsub is disposed only in the dummy cell region CRd, and is not disposed in the memory cell region CR. Hereby, with respect to any one of the fingers FGR0 to FGR3 which are disposed within the memory cell region CR, the current path of the source line SL is formed so as to include the source line contacts LIsrc on both sides. Therefore, the current flowing into the memory cell, may be dispersed on both sides of each finger FGR. That is, the unevenness of the source line voltage Vsrc and the unevenness of the cell current between the fingers FGR0 to FGR3, are suppressed, and it is possible to obtain the more stable cell properties.

(B) According to the above (A) configuration according to the first embodiment, it is possible to reduce the number of the shunt wiring layers that are the subsidiary wiring of the main wiring layer which is included in the wiring layer WRsrc.

The shunt wiring layer is the wiring of the low resistance. A large number of the shunt wiring layers are provided, and thereby, it is possible to reduce the wiring resistance of the path including the shunt wiring layer. Accordingly, for example, it is possible to relax the local rise of the source line voltage Vsrc in the wiring layer WRsrc. Moreover, the source line voltage Vsrc which may be applied to the all of the wiring layer WRsrc, may be still more close to a standard voltage. The region where the plurality of shunt wiring layers are disposed together, is referred to as a shunt region.

For example, in the configuration of the above comparative examples, the source line voltage Vsrc locally rises in the vicinity of the fingers FGR0r and FGR3r which are adjacent to the substrate contact LIsub_r. In order to suppress the local rise, for example, the number of sheets of the source line contacts LIsrc_r are increased, but it may not be easy to manufacture such a layout of the memory cell array. Therefore, in accordance with the maximum value of the change of the source line voltage Vsrc in the vicinity of the fingers FGR0r and FGR3r which are adjacent to the substrate contact LIsub_r, it may be necessary to provide a large number of shunt regions.

In the first embodiment, in any one of the fingers FGR0 to FGR3 which are disposed within the memory cell region CR, the local rise of the source line voltage Vsrc is suppressed. Accordingly, for example, it is possible to reduce the size of the shunt region in comparison with the configuration of the comparative examples. If the size of the shunt region is reduced, it is possible to lessen the chip size of the NAND type flash memory 1.

(C) According to the above (A) configuration according to the first embodiment, the resistance of the path leading to the n-type diffusion layer Wn from the wiring layer WRsrc, is lowered, and the voltage drop of the source line voltage Vsrc is suppressed. Accordingly, if the shunt region is not reduced, and is maintained, for example, it is possible to reduce the noise voltage Vnoise in the source line voltage Vsrc, in comparison with the configuration of the comparative examples. Hereby, it is possible to enhance the speed of the operations such as the reading, and operation reliability.

(D) According to the above (A) configuration according to the first embodiment, it is possible to separate the region of the p-type diffusion layer Wp of the semiconductor substrate Sub from the region of the n-type diffusion layer Wn. As a result, it is possible to suppress the influence of the p-type diffusion layer Wp on another region such as the n-type diffusion layer Wn of the semiconductor substrate Sub.

### (4) Layout Example of Memory Cell Array

Within the memory cell array 10 according to the first embodiment, layout examples of the memory cell region CR and the dummy cell region CRd, will be described below.

### Layout Examples 1 and 2

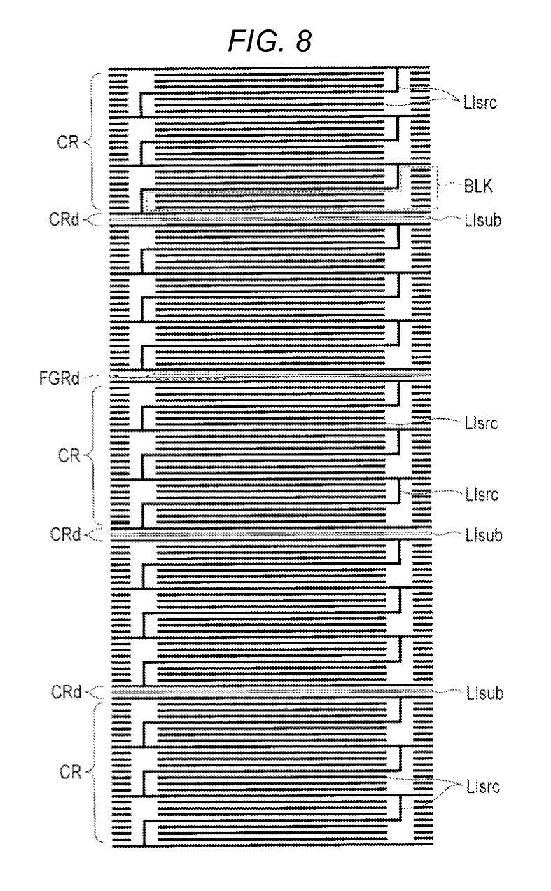

In Layout Example 1 of FIG. 8, the plurality of memory blocks BLK is assumed to be the memory cell region CR, and the dummy cell regions CRd are provided between each of the memory cell regions CR. The dummy cell region CRd, has two of the dummy fingers FGRd assigned thereto. Within the dummy cell region CRd, one sheet of the substrate contact LIsub is disposed.

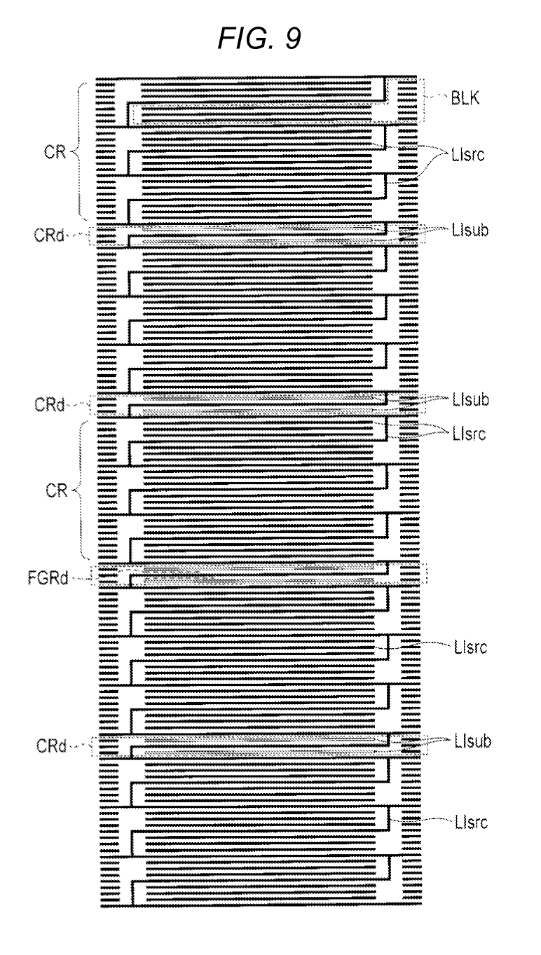

In Layout Example 2 of FIG. 9, the dummy cell region CRd has four of the dummy fingers FGRd assigned thereto, and two sheets of the substrate contacts LIsub are disposed. Layout Examples 3 to 5

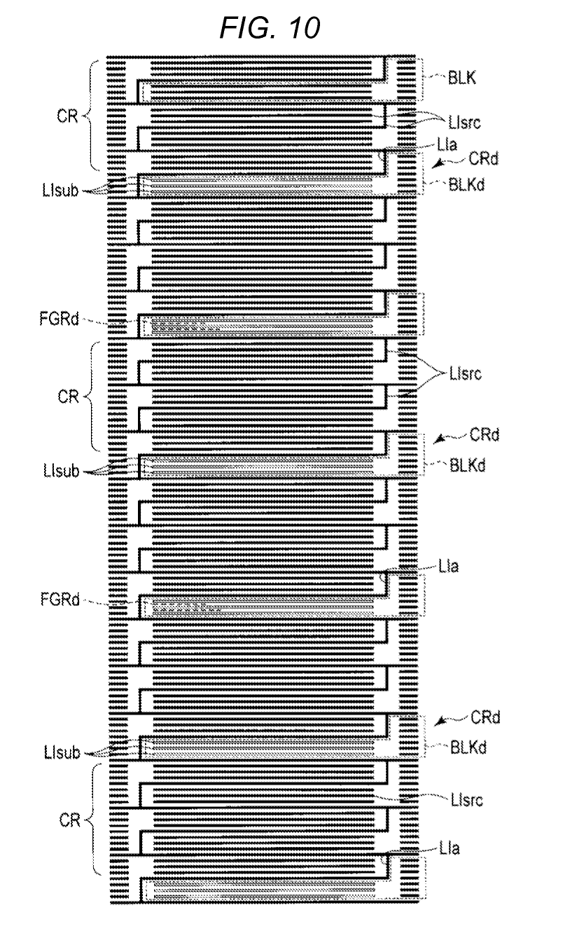

In layout examples 3 to 5 of FIG. 10 to FIG. 12, the dummy cell regions CRd are provided by the dummy block BLKd, between each of the memory cell regions CR.

For example, one dummy block BLKd includes four dummy fingers FGRd. For example, the dummy block BLKd has the same layout pattern as the memory block BLK including four fingers FGR. Between each of the dummy fingers FGRd, the substrate contacts LIsub are provided. In all of each drawings, the examples in which the substrate contacts LIsub are provided between the dummy fingers FGRd, are indicated, but it is not limited thereto. As long as at least one sheet of the substrate contact LIsub is included in the dummy block BLKd, it is favorable, and for example, some of the plate-shaped contacts LI between the dummy fingers FGRd, may be the source line contacts LIsrc.

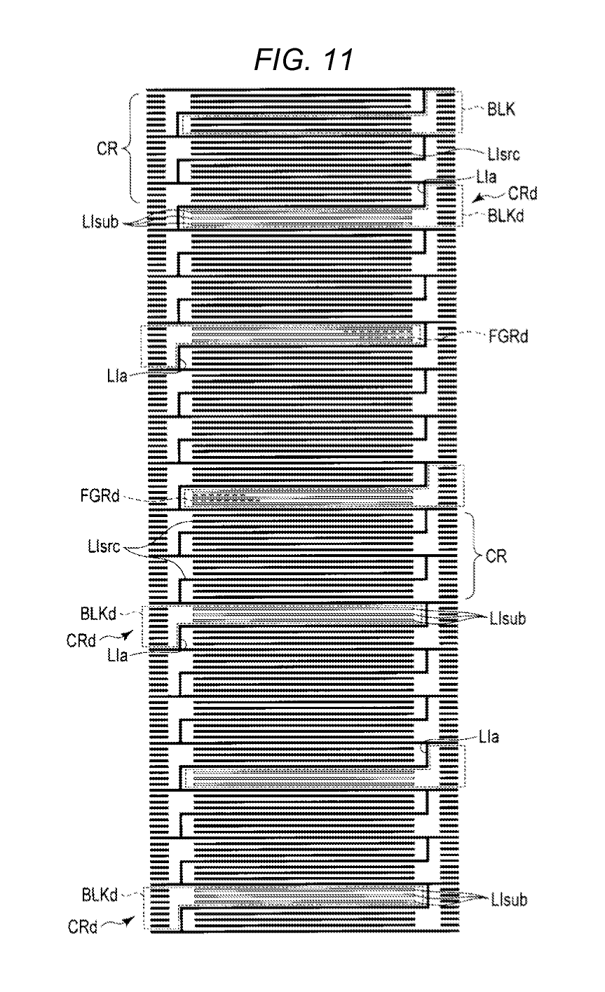

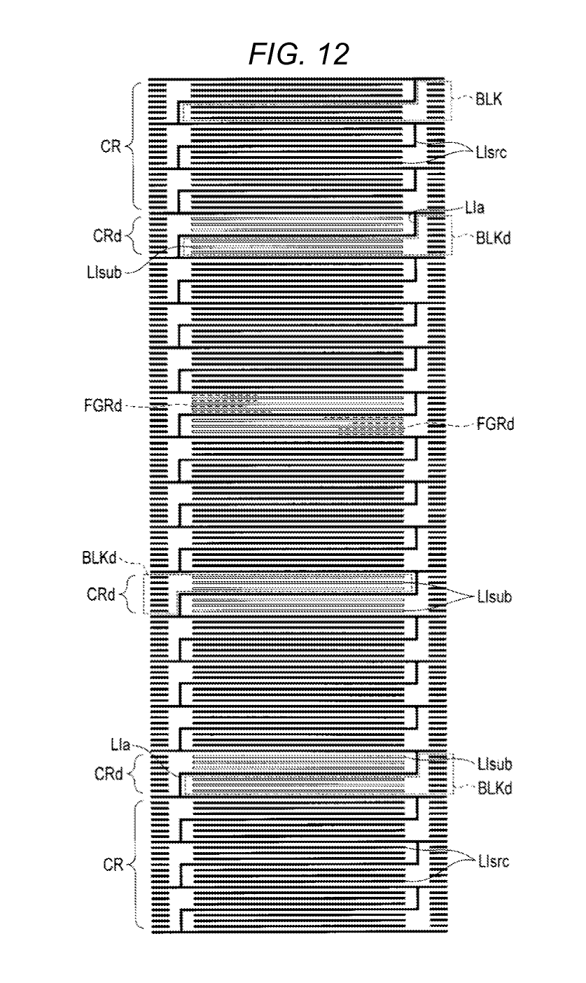

In Layout Example 3 of FIG. 10, between the plurality of memory blocks BLK, the dummy blocks BLKd are inserted one by one. In Layout Example 4 of FIG. 11, an insert position of the dummy block BLKd is changed alternately with respect to the plate-shaped contact LIa which is positioned on the border of the block. In Layout Example 5 of FIG. 12, between the plurality of memory blocks BLK, two dummy blocks BLKs are inserted through the plate-shaped contact LIa which is positioned on the border of the block.

### SECOND EMBODIMENT

A second embodiment is an example of a case where the dummy cell regions CRd are inserted by unit of the dummy block BLKd, between the memory cell regions CR, as the examples of FIG. 10 to FIG. 12. In a NAND type flash memory according to the second embodiment, the dummy block BLKd which is included in the dummy cell region CRd, is configured to be accessible.

### (1) Configuration of Dummy Block

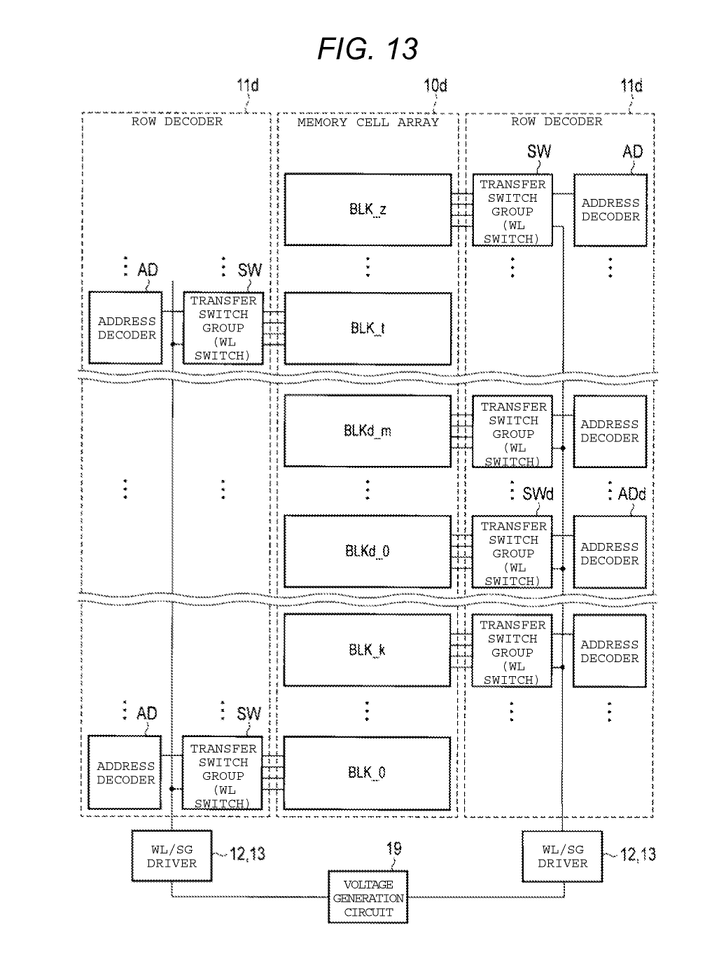

The dummy block BLKd according to the second embodiment, will be described using FIG. 13, with reference to FIG. 10 to FIG. 12. The operations of each portions described below, are performed by the control circuit 20 which receives the instruction from the outside, in the same manner as FIG. 1.

The dummy block BLKd according to the second embodiment includes the memory cell transistor as a dummy cell, two types of the selection gate transistors, three types of the selection gate lines which are connected to two types of the selection gate transistors, and the word line.

As illustrated in FIG. 13, within a row decoder 11d, an address decoder ADd, and a transfer switch group SWd including the word line switch, are assigned to the individual dummy blocks BLKd, respectively. The address decoder ADd and the transfer switch group SWd operate based on the address signal indicating the address of the assigned dummy cell. At which side of the row decoder 11d the address decoder ADd and the transfer switch group SWd are provided with respect to a memory cell array 10d, is caused by the pullout direction of the word line of the assigned dummy block BLKd.

By the above configuration, the control circuit 20 may supply various voltages which are necessary for the writing, the reading, and the erasing, to the dummy cell, and may perform the writing operation, the reading operation, and the erasing operation. Upon the access to the dummy block BLKd, a special command which is different from the command at the time of accessing the memory block BLK, is used. For example, the special command is configured by adding a sub-command not included in the command of the memory block BLK to the command of the memory block BLK, or changing the combination of the sub-command. Moreover, when the writing operation, the reading operation, and the erasing operation are performed with respect to the dummy cell, a special operation parameter which is different from an operation parameter with respect to the memory cell, is used. For example, in the special operation parameter, largeness or smallness of the voltage which is applied to each wiring, the time, the timing, or the like is changed so as to be suited to the dummy cell.

Moreover, when the writing operation or the reading operation is performed with respect to the memory block BLK, the voltage Vss is given to at least one of the selection gate line and the word line within the dummy block BLKd. Hereby, at least any one of the selection gate line and the word line is fit to the potential Vss. When the access to the memory block BLK, is not performed, that is, when the whole of the memory cell array 10d is in a standby state, the voltage Vss may be given to at least one of the selection gate line and the word line within the dummy block BLKd. All of the selection gate line and the word line may be in a floating state.

When the erasing operation is performed with respect to the memory block BLK, all of the selection gate line and the word line within the dummy block BLKd, are in the floating state. cl (2) Effects According to Second Embodiment

According to the second embodiment, one or a plurality of effects will be achieved, in addition to the effects according to the first embodiment.

(A) According to the second embodiment, the dummy block BLKd is provided within the dummy cell region CRd. As a result, it is possible to assign the transfer switch group SWd and the address decoder ADd to the individual dummy cells. Accordingly, it is possible to perform the writing operation, the reading operation, and the erasing operation with respect to the dummy cell, separately from the memory cell.

In this manner, the dummy block BLKd is configured to be capable of writing, reading and erasing, and thereby, for example, the writing may be performed into the dummy cell in advance. Upon access to the memory block BLK, the dummy block BLKd may be electrically connected to the bit line BL. Even in this case, the dummy cell into which the writing is performed in advance, is turned off. Accordingly, it is possible to suppress the leakage of the bit line through the dummy cell, or it is possible to suppress unintended activations such as the false reading from the dummy cell, and the like.

(B) According to the above (A) configuration of the second embodiment, for example, it is possible to use the dummy block BLKd as an extra block.

In the memory cell array, the extra block may be provided. When the initial failure or the breakdown is seen in any one of the memory blocks, the extra block is a block which may be used as an alternative block of such memory block. By configuring the dummy block BLKd so as to be capable of performing the writing operation, the reading operation, and the erasing operation, it is possible to assign the dummy block BLKd to the extra block.

(C) According to the second embodiment, the dummy block BLKd includes the dummy cell, the selection gate transistor, the selection gate line, and the word line. The row decoder 11d includes the transfer switch group SWd and the address decoder ADd. The transfer switch group SWd and the address decoder ADd operate based on the address signal indicating the address of the dummy cell.

Hereby, the memory cell array 10d and peripheral circuits thereof may be configured in the same manner as the layout of a case where the dummy cell region CRd is not provided. That is, if the layout of the n-type diffusion layer Wn and the p-type diffusion layer Wp which are formed in the semiconductor substrate Sub, is changed, the following process may be almost the same as the case where the dummy cell region CRd is not provided. Accordingly, it is possible to easily manufacture the NAND type flash memory.

(D) According to the second embodiment, when the writing operation or the reading operation is performed with respect to the memory cell, the potential Vss is applied to at least one of the selection gate line and the word line which are included in the dummy block BLKd. As a result, it is possible to suppress the occurrence of the bit line leakage through the dummy cell.

(E) According to the second embodiment, when the erasing operation is performed with respect to the memory cell, the selection gate line and the word line which are included in the dummy block BLKd, are in the floating state.

When the erasing operation is performed with respect to the memory block BLK, the voltage which is necessary for the erasing within the memory block BLK, is applied. The selection gate line and the word line within the dummy block BLKd are in the floating state, and thereby, it is possible to suppress the occurrence of a potential difference to the voltage of the erasing in the selection gate line and the word line. Accordingly, the breakdown of the dummy block BLKd is suppressed.

(F) According to the second embodiment, when the writing operation, the reading operation, and the erasing operation are performed with respect to the dummy cell, the control circuit 20 is instructed to access the dummy block BLKd by the special command. That is, in order to access the dummy block BLKd, the control circuit 20 is necessary to receive the special command from the outside. Hereby, it is possible to suppress the access to dummy block BLKd by mistake.

The substrate contacts LIsub are disposed on the periphery of the dummy cell. The dummy cell may not have the source line contact LIsrc in the vicinity thereof. Hence, the dummy cell may have the cell properties which are different from the cell properties of the memory cell. Accordingly, it may be not suitable to use the dummy cell as a memory element in the same manner as the memory cell. By using the special command in the access to the dummy block BLKd, it is possible to suppress the unintended activations such as the false reading from the dummy cell, and the like.

(G) According to the second embodiment, when the writing operation, the reading operation, and the erasing operation are performed with respect to the dummy cell, the control circuit 20 uses the special operation parameter.

As described above, the cell properties of the dummy cell may be different from the cell properties of the memory cell. The dummy cell may not have the source line contact LIsrc in the vicinity thereof. Even in this case, by using the special operation parameter which is suited to the dummy cell, the dummy cell may be operated more securely.

### (3) Modification Example According to Second Embodiment

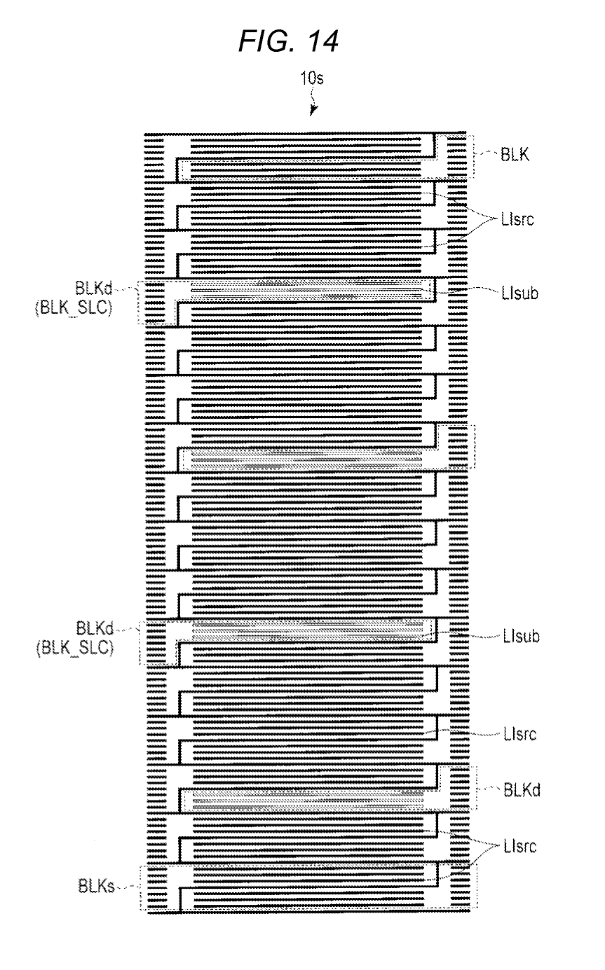

In a NAND type flash memory according to modification examples of the second embodiment, the dummy block BLKd is used as a special memory region. The modification examples of the second embodiment, will be described below using FIG. 14 to FIG. 17.

In Modification Example 1 of FIG. 14, the memory cell within the memory block BLK is used as a multi-level cell (MLC), and the dummy cell within the dummy block BLKd is used as a single-level cell (SLC). The SLC is a cell storing data of one bit, by properly using two of the threshold voltages (distribution) of the transistor in one cell. The MLC is a cell storing data of a plurality of bits, by properly using four or more of the threshold voltages (distribution) of the transistor in one cell. Furthermore, within a memory cell array 10s, an additional memory block BLKs is inserted. For example, the memory cell within the additional memory block BLKs, is used as an MLC.

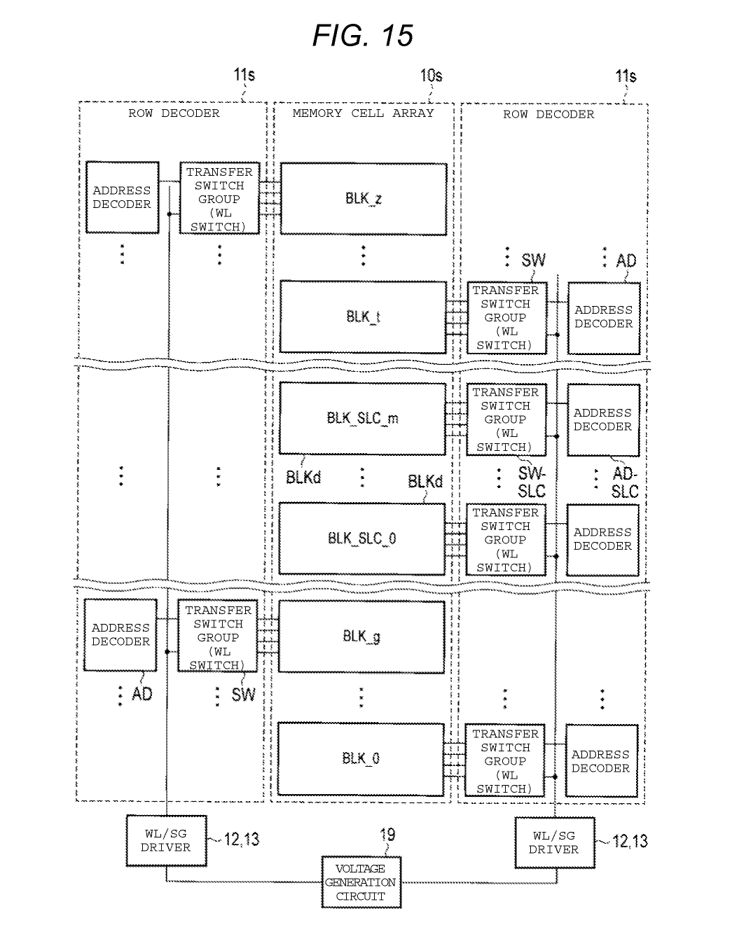

The dummy block BLKd is used as a special SLC block BLK_SLC. As illustrated in FIG. 15, within a row decoder 11s, an address decoder AD_SLC and a transfer switch group SW SLC are assigned also to the special SLC block BLK_SLC, respectively.

The substrate contacts LIsub are disposed in the vicinity of the dummy cell, and the cell properties of the dummy cell may be worse than the cell properties of the memory cell. The SLC may retain the data with the high reliability more than the MLC. By using the dummy cell as a SLC, it is possible to use the dummy cell as a memory element, even if the cell properties of the dummy cell is lower than the cell properties of the memory cell. Accordingly, it is possible to use the dummy block BLKd as an effective block. By the additional memory block BLKs, for example, memory capacity of the entire memory cell array 10s, is maintained at the same level as the memory cell array of the comparative examples described above.

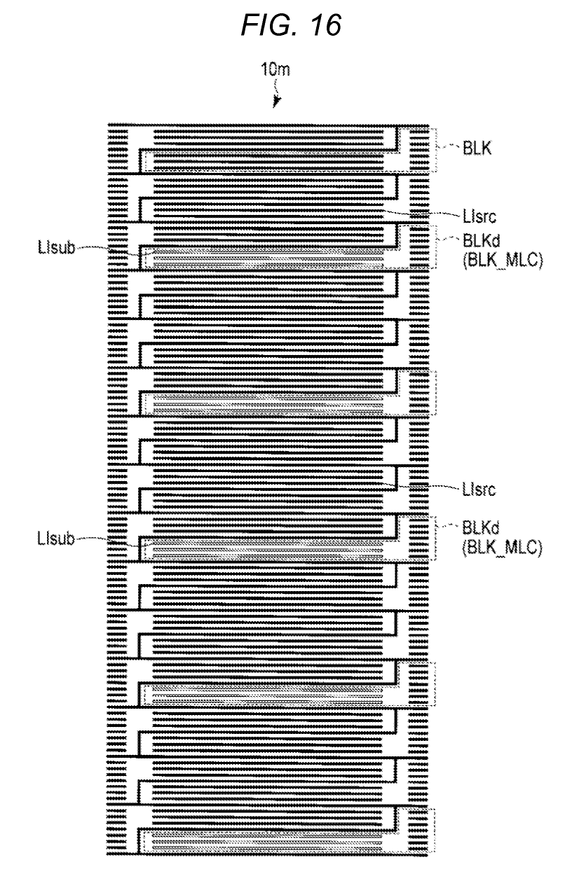

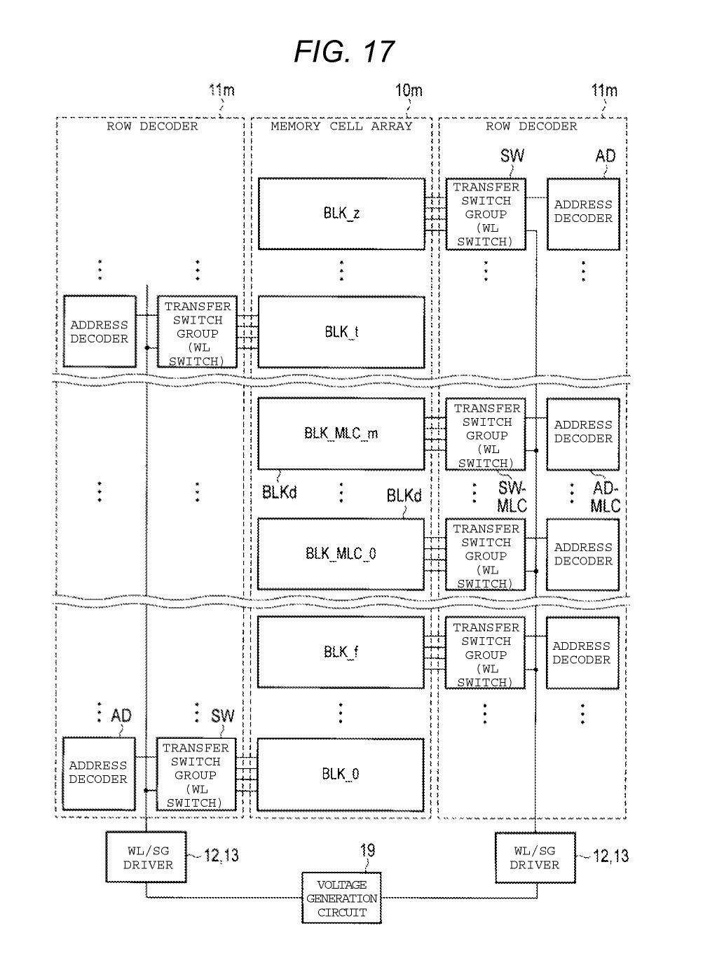

In Modification Example 2 of FIG. 16, the memory cell within the memory block BLK, and the dummy cell within the dummy block BLKd, are used as a MLC. The dummy block BLKd is used as a special MLC block BLK_MLC. As illustrated in FIG. 17, within a row decoder 11m, an address decoder AD_MLC and a transfer switch group SW MLC are assigned also to the special MLC block BLK_MLC, respectively.

The substrate contacts LIsub are disposed in the vicinity of the dummy cell, and the operation reliability of the dummy cell may be worse than the operation reliability of the memory cell. For example, the dummy block BLKd as a special MLC block BLK_MLC, is assigned to the intended use for which the high operation reliability is not asked. As a result, the additional block is not inserted, and for example, the memory capacity of the entire memory cell array 10m, may be maintained at the same level as the memory cell array of the comparative examples described above. That is, area penalty is not generated in the memory cell array 10m of Modification Example 2.

### OTHER EMBODIMENTS

As described above, each of the embodiments and the modification examples are described, but the above embodiments are illustrated as an example, and the technical idea of the above embodiments does not limit materials of the components, shapes, structures, disposition, or the like. The new embodiment may be executed in various other forms, and in an execution phase, it is possible to variously perform omission, redisposition, and change within the scope without departing from the gist. Furthermore, various phases are included in the embodiments described above, and various embodiments may be extracted by appropriately combining a plurality of disclosed components.

Each functional block may be realized by any one of hardware and computer software, or combining both of the hardware and the computer software. Hence, as it is clear that each function block is any one of the hardware and the computer software, the above description is generally made from the viewpoint of the functions. Those skilled in art may realized the functions thereof by various methods per specific embodiment, but any of the realization methods is included in the scope of the embodiments. Moreover, each functional block is not needed to be separated as described above. For example, a portion of the functions may be executed by the functional block which is different from the functional blocks of the examples. Furthermore, the functional blocks of the examples may be divided into small functional sub-blocks. The embodiments are not limited according to by which functional block is specified.

In the embodiments and the modification examples described above, several layout examples of the memory cell arrays 10, 10d, 10s and 10m are indicated, but it is not limited thereto. The number of the memory cell region and the dummy cell region which are included in the memory cell array, and the layout thereof are arbitrary. The number of the memory blocks and the dummy blocks which are included in the memory cell array, and the layout thereof are similar thereto. The number of sheets of the plate-shaped contacts which are included within the block, and itemized contents of the source line contact and the substrate contact within the dummy block, may be appropriately determined in accordance with various specifications.

In the embodiments described above, the example in which the word line WL is pulled out on both sides of the memory cell arrays 10, 10d, 10s and 10m, is described, but it is not limited thereto. The word line may be pulled out only on one side of the memory cell array.

In the embodiments described above, the example in which the fingers FGR and FGRd include the string units of four columns, and the blocks BLK and BLKd include four fingers FGR and FGRd, is described, but it is not limited thereto. The number of the string units which are included in the finger, and the number of the fingers which are included in the block, are arbitrary. The number of the layers of the word lines is similar thereto.

In the embodiments described above, the example in which the contact which is connected to the lower layer structure and the upper layer structure of the memory cell array 10, is assumed to be the plate-shaped contact LI, is described, but it is not limited thereto. For example, the lower layer structure and the upper layer structure of the memory cell array, are dotted along the X direction (row direction). The lower layer structure and the upper layer structure of the memory cell array, may be connected by the pillar-shaped contact. In such configuration, by applying the embodiments described above, it is possible to suppress the dispersion inhibition of the cell current which is caused by the layout of the substrate contact.

In the embodiments described above, the example in which the memory cell is assumed to be the MLC, is described, but it is not limited thereto. There is no problem that a binary memory system, a multi-value memory system, or the like is used as a memory system of the memory cell. In the memory cell of the multi-value memory system, an example of the reading operation, the writing operation, and the erasing operation, will be described below.

For example, in the reading operation of a multi-value level, the levels from the side where the threshold voltage is low, are assumed to be an A level, a B level and a C level in order. In the reading operation, for example, the voltage that is applied to the word line which is selected in the reading operation of the A level, is between 0 V and 0.55 V. The voltage is not limited thereto, and may be between 0.1 V and 0.24 V, between 0.21 V and 0.31 V, between 0.31 V and 0.4 V, between 0.4 V and 0.5 V, or between 0.5 V and 0.55 V. For example, the voltage that is applied to the word line which is selected in the reading operation of the B level, is between 1.5 V and 2.3 V. The voltage is not limited thereto, and may be between 1.65 V and 1.8 V, between 1.8 V and 1.95 V, between 1.95 V and 2.1 V, or between 2.1 V and 2.3 V. For example, the voltage that is applied to the word line which is selected in the reading operation of the C level, is between 3.0 V and 4.0 V. The voltage is not limited thereto, and may be between 3.0 V and 3.2 V, between 3.2 V and 3.4 V, between 3.4 V and 3.5 V, between 3.5 V and 3.6 V, or between 3.6 V and 4.0 V. For example, the time (tR) of the reading operation may be between 25 μs and 38 μs, between 38 μs and 70 μs, or between 70 μs and 80 μs.

The writing operation includes a program operation and a verify operation. In the writing operation, for example, the voltage that is firstly applied to the word line which is selected during the program operation, is between 13.7 V and 14.3 V. The voltage is not limited thereto, and may be between 13.7 V and 14.0 V, or between 14.0 V and 14.6 V. Therebetween, the voltage that is first applied to the word line which is selected at the time of writing the odd-numbered word line, may be different from the voltage that is first applied to the word line which is selected at the time of writing the even-numbered word line. When the program operation is performed as an incremental step pulse program (ISPP) system, for example, approximately 0.5 V is used as a voltage of step-up. For example, the voltage that is applied to the non-selected word line, may be between 6.0 V and 7.3 V. The voltage is not limited thereto, and for example, the voltage may be between 7.3 V and 8.4 V, and the voltage may be 6.0 V or less. Whether the non-selected word line is the odd-numbered word line, or whether the non-selected word line is the even-numbered word line, and according thereto, the applied pulse voltage may be different. For example, the time (tProg) of the writing operation may be between 1,700 μs and 1,800 μs, between 1,800 μs and 1,900 μs, or between 1,900 μs and 2,000 μs.

In the erasing operation, for example, the voltage that is firstly applied to the well which is disposed above the semiconductor substrate, and in which the memory cell is disposed above, is between 12 V and 13.6 V. The voltage is not limited thereto, and for example, the voltage may be between 13.6 V and 14.8 V, between 14.8 V and 19.0 V, between 19.0 V and 19.8 V, or between 19.8 V and 21 V. For example, the time (tErase) of the erasing operation may be between 3,000 μs and 4,000 μs, between 4,000 μs and 5,000 μs, or between 4,000 μs and 9,000 μs.

Moreover, for example, the memory cell may have the structure as follows. The memory cell has an electrical charge accumulating film that is disposed through a tunnel insulating film of which a film thickness is 4 nm to 10 nm on the semiconductor substrate such as a silicon substrate. The electrical charge accumulating film may have a layered structure of an insulating film such as a silicon nitride (SiN) film of which the film thickness is 2 nm to 3 nm, or a silicon oxide (SiON) film of which the film thickness is 2 nm to 3 nm, and a polysilicon (Poly-Si) film of which the film thickness is 3 nm to 8 nm. The metal such as ruthenium (Ru) may be added to the polysilicon film. The memory cell has the insulating film on the electrical charge accumulating film. For example, the insulating film has a silicon oxide (SiO₂) film of which the film thickness is 4 nm to 10 nm. The silicon oxide film is interposed between a lower layer High-k film of which the film thickness is 3 nm to 10 nm, and an upper layer High-k film of which the film thickness is 3 nm to 10 nm. As a material of the High-k film, hafnium oxide (HfO), or the like is used. Additionally, the film thickness of the silicon oxide film may be thicker than the film thickness of the High-k film. On the insulating film, a control electrode of which the film thickness is 30 nm to 70 nm, is provided through a film of the film thickness 3 nm to 10 nm. Here, as a film for the work function adjustment, for example, a metal oxide film such as tantalum oxide (TaO), a metal nitride film such as tantalum nitride (TaN), or the like is used. As a control electrode, tungsten (W) or the like may be used. It is possible to place air gaps between the memory cells.

The configuration of the memory cell array may be as described in U.S. Unexamined Patent Application Publication No. 2009/0267128 (U.S. patent application Ser. No. 12/407,403) which is entitled “Three dimensional stacked nonvolatile semiconductor memory”. Moreover, the configuration of the memory cell array may be as described in U.S. Unexamined Patent Application Publication No. 2009/0268522 (U.S. patent application Ser. No. 12/406,524) which is entitled “Three dimensional stacked nonvolatile semiconductor memory”, U.S. Unexamined Patent Application Publication No. 2010/0207195 (U.S. patent application Ser. No. 12/679,991) which is entitled “Non-volatile semiconductor storage device and method of manufacturing the same”, and U.S. Unexamined Patent Application Publication No. 2011/0284946 (U.S. patent Application Ser. No. 12/532,030) which is entitled “Semiconductor memory and method for manufacturing same”. All of the above patent applications are incorporated by reference herein in their entirety.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a memory cell region including adjacent first and second blocks of memory cells, wherein all the memory cells in each block are erased collectively and each of the blocks includes a plurality of stacks of memory cells above a semiconductor substrate;
a dummy cell region including a plurality of stacks of dummy cells above the semiconductor substrate;
a source line contact electrically connected to an upper wiring layer and through which a voltage is applied to a source line of the memory cells, wherein the source line contact is in contact with the semiconductor substrate and disposed between the first and second blocks; and
a substrate contact electrically connected to the upper wiring layer and through which a voltage is applied to the semiconductor substrate, wherein the substrate contact is in contact with the semiconductor substrate and is separated from any one of the stacks of memory cells by at least one stack of dummy cells.

2. The device according to claim 1,
wherein the semiconductor substrate has well regions of first and second conductivity types, and the source line contact is in contact with the well region of the first conductivity type and the substrate contact is in contact with the well region of the second conductivity type.

3. The device according to claim 1,
wherein the source line contact and the substrate contact have a plate shape and extend in a first direction that crosses a second direction along which the first and second blocks are arranged.

4. The device according to claim 3,
wherein the stacks of memory cells in the first block, the stacks of memory cells in the second block, and the stacks of dummy cells are arranged along the second direction.

5. The device according to claim 4, further comprising:
additional source line contacts having a plate shape and extending in the first direction, each of which is disposed between different adjacent stacks of memory cells.

6. The device according to claim 4, further comprising:
additional substrate contacts having a plate shape and extending in the first direction, each of which is disposed between different adjacent stacks of dummy cells.

7. The device according to claim 3,
wherein the substrate contact is disposed between adjacent stacks of dummy cells.

8. The device according to claim 3,
wherein the source line contact is directly adjacent one of the stack of memory cells and one of the stacks of dummy cells.

9. The device according to claim 1,
wherein the first and second blocks have the same number of stacks of memory cells.

10. The device according to claim 9,
wherein the number of stack of dummy cells in the dummy region is one-half the number of stacks of memory cells in the first or second block.

11. The device according to claim 9,
wherein the number of stack of dummy cells in the dummy region is the same as the number of stacks of memory cells in the first or second block.

12. The device according to claim 11, further comprising:
another source line contact that is disposed between adjacent stacks of dummy cells.

13. The device according to claim 9,
wherein the number of stack of dummy cells in the dummy region is twice the number of stacks of memory cells in the first or second block.

14. The device according to claim 13, further comprising:
another source line contact that is disposed between adjacent stacks of dummy cells.

15. A semiconductor memory device comprising:
a memory cell region including adjacent first and second blocks of memory cells, wherein all the memory cells in each block are erased collectively and each of the blocks includes a plurality of stacks of memory cells above a semiconductor substrate;
a dummy cell region including a dummy block of dummy cells, the dummy block including a plurality of stacks of dummy cells above the semiconductor substrate;
a source line contact electrically connected to an upper wiring layer and through which a voltage is applied to a source line of the memory cells, wherein the source line contact is in contact with the semiconductor substrate and disposed between the first and second blocks;
a substrate contact electrically connected to the upper wiring layer and through which a voltage is applied to the semiconductor substrate, wherein the substrate contact is in contact with the semiconductor substrate and is separated from any one of the stacks of memory cells by at least one stack of dummy cells; and
a control circuit including a first address decoder for the first block of memory cells, a second address decoder for the second block of memory cells, and a third address decoder for the dummy block of dummy cells.

16. The device according to claim 15,
wherein the semiconductor substrate has well regions of first and second conductivity types, and the source line contact is in contact with the well region of the first conductivity type and the substrate contact is in contact with the well region of the second conductivity type.

17. The device according to claim 15,
wherein the source line contact and the substrate contact have a plate shape and extend in a first direction that crosses a second direction along which the first and second blocks are arranged.

18. The device according to claim 15,
wherein the memory cells are configured to store data of more than one bit and the dummy cells are configured to store data of one bit.

19. The device according to claim 15,
wherein the memory cells are configured to store data of more than one bit and the dummy cells are configured to store data of more than one bit.

20. The device according to claim 15, further comprising:
another dummy cell region including a dummy block of dummy cells,
wherein the dummy cell regions are separated by multiple blocks of memory cells.
